(19) United States
(12) Patent Application Publication
(10) Pub. No.: US 2022/0181127 A1
(43) Pub. Date: Jun. 9, 2022

(54) ELECTROSTATIC CHUCK SYSTEM

(71) Applicant: Lam Research Corporation, Fremont, CA (US)

(72) Inventors: Ann ERICKSON, Lake Oswego, OR (US); David Joseph WETZEL, Santa Clara, CA (US); Oleksandr MIKHNENKO, San Diego, CA (US); Seyedalireza TORBATISARRAF, San Jose, CA (US)

(21) Appl. No.: 17/604,956

(22) PCT Filed: May 6, 2020
(86) PCT No.: PCT/US2020/031674

§ 371 Date: Oct. 19, 2021

Related U.S. Application Data
(60) Provisional application No. 62/844,224, filed on May 7, 2019.

(51) Int. Cl. H01J 37/32; H01L 21/683

(52) U.S. Cl. CPC H01J 37/32724; H01J 37/3244; H01L 21/6833

(57) ABSTRACT

An electrostatic chuck system is provided. A plate has gas apertures. A body formed by an additive process on a first side of the plate. The body has channels in fluid connection with the gas apertures, coolant channels, and support structure for supporting the gas channels and the coolant channels

### CROSS-REFERENCE TO RELATED APPLICATION

This application claims the benefit of priority of U.S. Application No. 62/844,224, filed May 7, 2019, which is incorporated herein by reference for all purposes.

### BACKGROUND

The disclosure relates to a plasma processing chamber for forming semiconductor devices on a semiconductor wafer. The disclosure more specifically relates to an electrostatic chuck system for a plasma processing chamber.

In the formation of semiconductor devices, plasma processing chambers are used to process the semiconductor devices. The plasma processing chamber may use an electrostatic chuck. The electrostatic chuck may be subjected to corrosive plasma and high electrostatic potentials. To improve resistance to erosion by corrosive plasma metal oxide coatings may be used. Metal oxide is typically brittle, subject to cracking, and has relatively low coefficients of thermal expansion.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, an electrostatic chuck system is provided. A plate has gas apertures. A body formed by an additive process is on a first side of the plate. The body has channels in fluid connection with the gas apertures, coolant channels, and support structure for supporting the gas channels and the coolant channels.

In another manifestation, a method for forming an electrostatic chuck system is provided. A plate is formed with gas apertures. A body is printed on a first side of the plate. The body comprises gas channels in fluid connection with the gas apertures, coolant channels, and support structure for supporting the gas channels and the coolant channels.

In another manifestation, an apparatus for plasma processing substrates is provided. A plasma processing chamber is provided. An electrostatic chuck is within the plasma processing chamber, wherein the electrostatic chuck comprises a plate with gas apertures and a body formed by an additive process on a first side of the plate. The body comprises gas channels in fluid connection with the gas apertures, coolant channels, and support structure for supporting the gas channels and the coolant channels.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-C are bottom views of embodiments.

FIGS. 3A-D are side-views of an embodiment.

FIG. 4 is a cross-sectional view of an embodiment.

FIG. 5 is a cross-sectional view of another embodiment.

FIG. 6 is a schematic view of a plasma processing chamber that may employ an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Materials that provide resistance to arcing are typically a metal oxide. Metal oxide is typically brittle, subject to cracking, and has relatively low coefficients of thermal expansion (CTE). Any crack induced through cycling across a wide range of temperatures will lead to electrical breakdown, causing the part to fail.

Current protective coatings on electrostatic chuck (ESC) baseplates include anodization, ceramic spray coat, or a spray coat on top of anodization. An aluminum nitride coating grown directly on the surface of aluminum baseplates is used in some products. Anodization breaks down at approximately 2 kilovolts (kV) on a 0.002 inch thick coating when on a flat surface of aluminum, and at 600 volts (V) on corner radii. Spray coating, if applied normal to the surface, will withstand up to 10 kV on flat surfaces, but only about 4-5 kV on corner radii. Spray coats can be sealed with polymers, but all known effective sealing methods will degrade, when exposed to, in particular, to fluorine containing plasmas under chamber operating conditions. Existing technology reaches its limits at these values since attempts to further improve the breakdown by making thicker coatings lead to cracking in response to thermal cycling, due to a mismatch between the CTE of the substrate and the CTE of coating materials.

The metal parts of an ESC can be subjected to large voltages as compared to the chamber body. There is a need to protect the metal parts of ESCs from chemical degradation and electrical discharge.

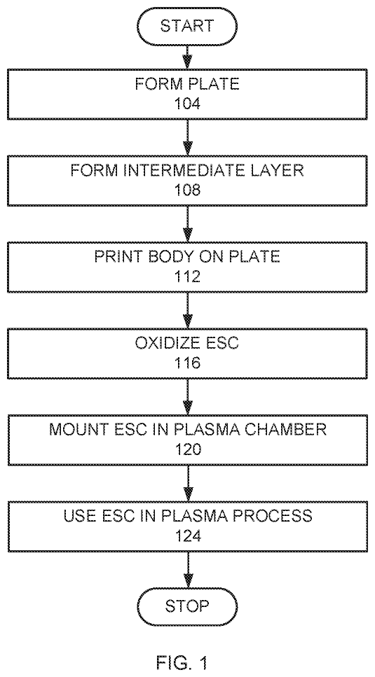

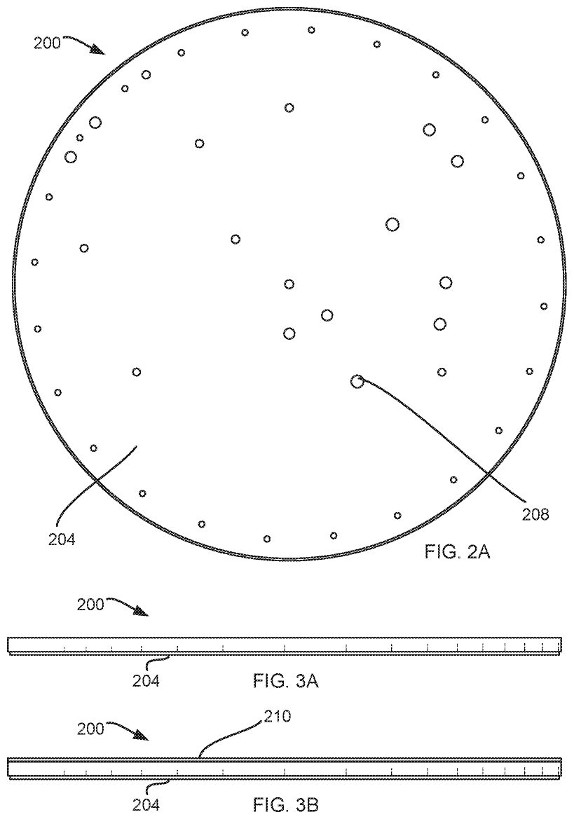

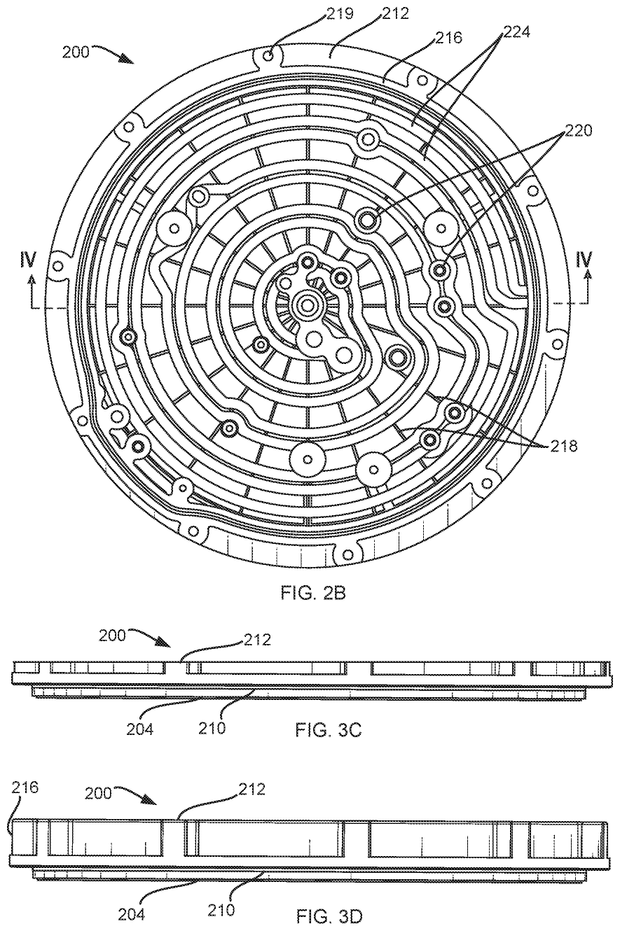

Various embodiments provide ESCs that are resistant to damage by arcing and/or erosion. FIG. 1 is a flow chart of an embodiment for providing an ESC system. A plate is formed (step 104). FIG. 2A is a bottom view of a plate 204 used in an ESC system 200 provided in an embodiment. The bottom view of the plate 204 shows a first side of the plate 204. The first side of the plate 204 in this embodiment is a flat surface. In this embodiment, the plate 204 is a plate 204 of Al-SiC. Al-SiC is a metal matrix composite, comprising an aluminum matrix with silicon carbide (SiC) particles. An ESC system 200 made using a plate 204 from Al-SiC would have significant advantages over previous base plate technology. Alloys based on the aluminum-silicon carbide (Al-SiC) system provide a balance of low CTE with high thermal conductivity. The plate 204 comprises a plurality of gas apertures 208. FIG. 3A is a side view of the plate 204 of the ESC system 200.

After the plate 204 is provided, an intermediate layer is formed on a side of the plate 204 (step 108). In this embodiment, the intermediate layer is aluminum 6061 deposited as a supersonic spray. Aluminum 6061 is an aluminum alloy with magnesium and silicon. FIG. 3B is a side view of the plate 204 of the ESC system 200 after the intermediate layer 210 has been formed on a first side of the plate 204.

After the intermediate layer 210 is formed, a body is printed on the plate 204 (step 112). The body is printed on the intermediate layer 210 on the first side of the plate 204. An additive process, known as 3D printing, is used to print the body on the plate 204. In this embodiment, the material of the plate 204 has a coefficient of thermal expansion, the material of the body has a coefficient of thermal expansion, and the material of the intermediate layer 210 has a coefficient of thermal expansion. In this embodiment, the coefficient of thermal expansion of the material of the intermediate layer is between the coefficient of thermal expansion of the material of the plate and the coefficient of thermal expansion of the material of the body. In some embodiments, the coefficient of thermal expansion of the material of the intermediate layer is closer to the midpoint value between the coefficient of thermal expansion of the material of the plate and the coefficient of thermal expansion of the material of the body than either the coefficient of thermal expansion of the material of the plate or the coefficient of thermal expansion of the material of the body. In some embodiments, the intermediate layer 210 facilitates the 3D printing of the body, by increasing the adhesion of the body. Such an intermediate layer 210 would be of a material with high adherence to both the material of the plate 204 and the material of the body. The additive process forms the body in a plurality of layers, using a layer by layer formation process.

FIG. 3C is a side view of the plate 204 of the ESC system 200 after one or more layers of the body 212 have been printed on the intermediate layer 210 on the first side of the plate 204. The additive process continues to print additional layers until the printing of the body 212 is completed. In this embodiment, a laser powder bed fusion process is used to print the body 212. The laser powder bed fusion process is also known as direct metal laser sintering or direct metal laser melting. In this embodiment, a powder of aluminum-silicon-magnesium is laser sintered to form each layer. Such a process provides a body 212 with a porosity of less than 0.5%. In another embodiment, an alpha-beta titanium alloy, such as Ti-6Al-4V alloy (designated as R56400) is printed on the intermediate layer 210 on top of an Al-SiC baseplate to form a bi-metal ESC system 200. This embodiment has advantages of low CTE and heat conductivity simultaneously. In this embodiment, intermediate layer 210 is in contact with a side of the plate 204 and the body 212.

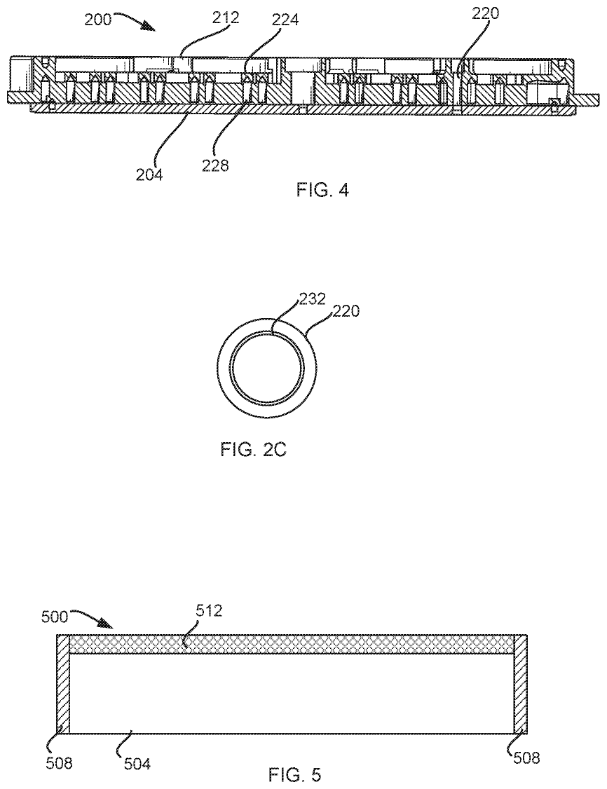

FIG. 2B is a bottom view of the ESC system 200 after the body 212 is completed. FIG. 3D is a side view of the ESC system 200 after the body 212 is completed. The body 212 comprises a circumferential flange 216 extending around a circumference of the body 212. In this embodiment, the circumferential flange 216 is perpendicular to the surface of the first side of the plate 204. Within an area enclosed by the circumferential flange 216 is a spider web support structure 218 of radial spokes. The spider web support structure 218 supports a plurality of gas channels 220 in fluid connection with the gas apertures 208. In this embodiment, the gas channels 220 have a length that is substantially perpendicular to the surface of the first side of the plate 204. In addition, the spider web support structure 218 supports a plurality of coolant channels 224. The circumferential flange 216 and bolt holes 219 are used for mounting the ESC system 200 in a plasma processing chamber. By printing a spider web support structure 218 of radial spokes instead of a flat plate, less material is used. FIG. 4 is a cross-sectional view of the ESC system 200 of FIG. 2B, along cut line IV-IV. A cross-sectional view of the coolant channels 224 shows the apertures 228 forming the coolant channels 224. Liquid coolant is able to flow through the coolant channels 224 in a direction substantially parallel to the surface of the first side of the plate 204. Instead of the apertures 228 having a horizontal surface on the side furthest from the plate 204, sloped surfaces are provided to facilitate the printing process.

After the body 212 is printed, the ESC system 200 is oxidized (step 116), forming an oxide layer. In this embodiment, a plasma electrolytic oxidation (PEO) process is used to form an oxide layer over the surface of the ESC system 200, providing a plasma electrolytic oxidation layer. In some embodiments, parts of the ESC system 200 are masked, so that only part of the ESC system 200 is oxidized. The ESC system 200 is mounted in a plasma processing chamber (step 120). In this embodiment, a ceramic plate is placed over the plate 204. A gas source is placed in fluid connection with the gas apertures 208. In this embodiment, the gas source provides helium. The helium is provided to transfer heat between the ceramic plate and the plate 204. A coolant source is placed in fluid connection with the coolant channels 224. The coolant source provides a coolant to control the temperature of the ESC system 200. The ESC system 200 supports a substrate that is to be processed. The ESC system 200 is used in plasma processing a substrate (step 124). The substrate is processed. The ESC system 200 supports the substrate during the process. The ESC system 200 is exposed to plasma and high electrical potentials that could cause arcing.

Printing the body 212 on the plate 204 provides a body 212 that may have complex coolant channel 224 patterns. The complex coolant channel 224 patterns may provide a more uniform temperature distribution across the surface of the plate 204. The oxide layer formed by PEO provides an improved protective layer on more complex shapes that is more resistant to arcing or other damages. Printing the body 212 may also allow for more complex gas channels 220 to help mitigate sparking.

In other embodiments, the body 212 and/or the plate 204 may be formed from one or more dielectric materials. For example, in some embodiments, the body 212 and/or plate 204 is formed from an electrically insulative ceramic material. In other embodiments, the body 212 is printed directly on the plate 204 without an intermediate layer 210. In other embodiments, the plate 204 and body 212 are formed from a metal containing material.

In other embodiments, instead of oxidizing the ESC system 200, during the printing of the body 212, various surfaces are coated with a protective coating. Such a process would print one or more layers of the body 212 and then coat various surfaces of the ESC system 200 with a protective coating. Additional layers of the body 212 are then printed. The printing of one or more layers of the body 212 and depositing a protective coating may be cyclically repeated several times. The protective coating may be provided by a spray process, such as an aerosol spray or thermal spray process. In other embodiments, the protective coating may be provided using a printing process. Some printing processes are able to print two different materials. Such processes would be able to print both the body 212 and a protective coating on surfaces of the body 212. The coating of some of the surfaces of the body 212 before all of the layers of the body 212 are printed allows for coating surfaces that would be difficult to coat once the body is completed. FIG. 2C is an enlarged view of a gas channel 220 with a protective coating 232 in the inside of the gas channel 220. In this example, a layer of the protective coating 232 is printed with each layer of the body 212, allowing the coating of the insides of the gas channels 220.

In another embodiment, an ESC system comprising an ESC body surrounded by a replaceable dielectric side sleeve is provided. FIG. 5 is a cross-sectional view of an ESC system 500 comprising an ESC body 504 surrounded by a replaceable dielectric side sleeve 508. In this embodiment, the ESC body 504 is made of aluminum. A ceramic plate 512 is bonded to an upper surface of the ESC body 504. In this embodiment, the ceramic plate 512 is made of an aluminum oxide ceramic. In this embodiment, the replaceable dielectric side sleeve 508 is a ring-shaped sleeve formed from polytetrafluoroethylene (PTFE). The replaceable dielectric side sleeve 508 is replaceable in that after the replaceable dielectric side sleeve 508 is sufficiently degraded, the replaceable dielectric side sleeve 508 is removed and a new replaceable dielectric side sleeve 508 may be slid around the ESC body 504. The replaceable dielectric sleeve 508 is replaceable in that it can be removed from the ceramic plate 512 and ESC body 504 and a new replaceable dielectric sleeve 508 may be placed around the ceramic plate 512 and ESC body 504. In this embodiment, the 3D printing process prints an ESC body 504 that has a rough outer surface that is not smooth enough to provide a satisfactory ESC system 500. The rough outer surface creates gaps that may cause lightup between the ESC system 500 and the edge ring. The replaceable dielectric side sleeve 508 is made of a soft or conforming material that accommodates rough edges of the ESC body 504 and provides a smooth outer surface that reduces gaps between the ESC body 504 and the edge ring to prevent lightup.

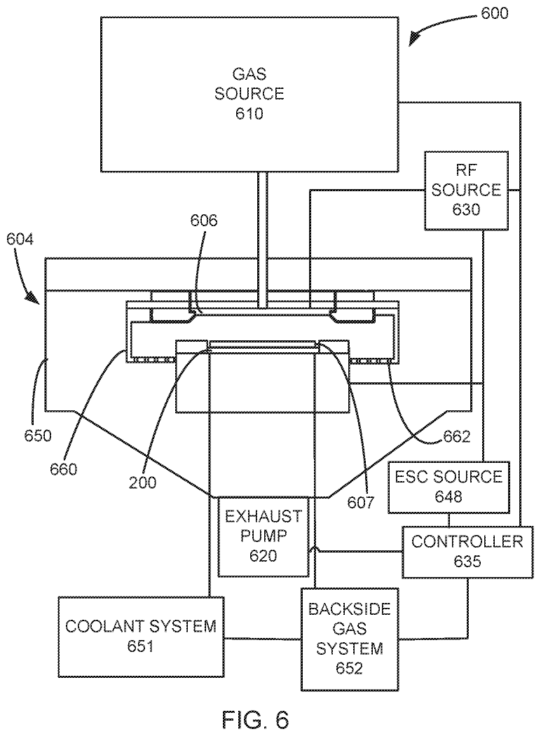

FIG. 6 is a schematic view of a plasma processing system 600 for plasma processing substrates, where the component may be installed in an embodiment. In one or more embodiments, the plasma processing system 600 comprises a gas distribution plate 606 providing a gas inlet and the ESC system 200, within a plasma processing chamber 604, enclosed by a chamber wall 650. Within the plasma processing chamber 604, a substrate 607 is positioned on top of the ESC system 200. An ESC power source 648 may provide a bias power to the ESC system 200. A gas source 610 is connected to the plasma processing chamber 604 through the gas distribution plate 606. A coolant system 651 is in fluid connection with the coolant channels 224 of the ESC system 200 and provides temperature control of the ESC system 200. A backside gas system 652 is in fluid connection with the gas channels 220. In this embodiment, the backside gas system 652 provides a flow of helium. A radio frequency (RF) power source 630 provides RF power to the ESC system 200 and an upper electrode. In this embodiment, the upper electrode is the gas distribution plate 606. In a preferred embodiment, 13.56 megahertz (MHz), 2 MHz, 60 MHz, and/or optionally, 27 MHz power sources make up the RF power source 630 and the ESC power source 648. A controller 635 is controllably connected to the RF power source 630, the ESC power source 648, an exhaust pump 620, and the gas source 610. A high flow liner 660 is a liner within the plasma processing chamber 604. The high flow liner 660 confines gas from the gas source and has slots 662. The slots 662 maintain a controlled flow of gas to pass from the gas source 610 to the exhaust pump 620. An example of such a plasma processing chamber is the Exelan Flex™ etch system manufactured by Lam Research Corporation of Fremont, Calif. The process chamber can be a CCP (capacitively coupled plasma) reactor or an ICP (inductively coupled plasma) reactor.

The plasma processing chamber 604 is used to plasma process the substrate 607. The plasma processing may be one or more processes of etching, depositing, passivating, or another plasma process. The plasma processing may also be performed in combination with nonplasma processing. Such processes may expose the ESC system 200 to plasmas containing halogen and/or oxygen.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An electrostatic chuck system, comprising:
a plate with gas apertures; and
a body formed by an additive process on a first side of the plate, wherein the body comprises:
gas channels in fluid connection with the gas apertures;
coolant channels; and
support structure for supporting the gas channels and the coolant channels.

2. The electrostatic chuck system, as recited in claim 1, wherein the plate is a metal containing plate and wherein the body is formed from a metal containing material.

3. The electrostatic chuck system, as recited in claim 2, further comprising an oxide layer on at least one of a surface of the plate or a surface of the body.

4. The electrostatic chuck system, as recited in claim 3, wherein the oxide layer is a plasma electrolytic oxidation layer.

5. The electrostatic chuck system, as recited in claim 1, wherein the plate is made of Al-SiC.

6. The electrostatic chuck system, as recited in claim 5, wherein the body is formed from a material comprising aluminum, silicon, and magnesium.

7. The electrostatic chuck system, as recited in claim 1, wherein the body further comprises a circumferential flange extending around the gas channels and the coolant channels.

8. The electrostatic chuck system, as recited in claim 1, further comprising an intermediate layer between the plate and the body.

9. The electrostatic chuck system, as recited in claim 8, wherein the plate has a coefficient of thermal expansion and the body has a coefficient of thermal expansion and the intermediate layer has a coefficient of thermal expansion, wherein the coefficient of thermal expansion of the intermediate layer is between the coefficient of thermal expansion of the plate and the coefficient of thermal expansion of the body.

10. The electrostatic chuck system, as recited in claim 1, further comprising a replaceable dielectric side sleeve surrounding the plate and the body.

11. The electrostatic chuck system, as recited in claim 10, wherein the replaceable dielectric side sleeve comprises polytetrafluoroethylene.

12. A method for forming an electrostatic chuck system, comprising:
forming a plate with gas apertures;
printing a body on a first side of the plate, wherein the body comprises:
gas channels in fluid connection with the gas apertures;
coolant channels; and
support structure for supporting the gas channels and the coolant channels.

13. The method, as recited in claim 12, wherein the forming the plate comprises casting a plate made of Al-SiC.

14. The method, as recited in claim 13, wherein the printing the body prints the body by sintering layers of a powder comprising aluminum, silicon, and magnesium.

15. The method, as recited in claim 12, further comprising oxidizing at least one of a surface of the plate and a surface of the body.

16. The method, as recited in claim 15, wherein the oxidizing the at least one of the surface of the plate and the surface of the body, comprises a plasma electrolytic oxidation process.

17. The method, as recited in claim 12, wherein the printing the body comprises printing the body out of a ceramic material.

18. The method, as recited in claim 17, wherein the printing the body, comprises printing the body as a plurality of layers, further comprising coating insides of gas channels with an insulative coating between printing layers of the plurality of layers.

19. The method, as recited in claim 12, further comprising forming an intermediate layer on the plate, wherein the body is formed on the intermediate layer and wherein and wherein the plate has a coefficient of thermal expansion and the body has a coefficient of thermal expansion and the intermediate layer has a coefficient of thermal expansion, wherein the coefficient of thermal expansion of the intermediate layer is between the coefficient of thermal expansion of the plate and the coefficient of thermal expansion of the body.

20. The method, as recited in claim 12, further comprising placing a replaceable dielectric side sleeve around the plate and the body.

21. The method, as recited in claim 20, wherein the replaceable dielectric side sleeve comprises polytetrafluoroethylene.

22. An apparatus for plasma processing substrates, comprising:
a plasma processing chamber;
an electrostatic chuck within the plasma processing chamber, wherein the electrostatic chuck comprises:
a plate with gas apertures; and
a body formed by an additive process on a first side of the plate, wherein the body comprises:
gas channels in fluid connection with the gas apertures;
coolant channels; and
support structure for supporting the gas channels and the coolant channels.

23. The apparatus, as recited in claim 22, wherein the plate is a metal containing plate and wherein the body is formed from a metal containing material.

24. The apparatus, as recited in claim 23, further comprising an oxide layer on at least one of a surface of the plate or a surface of the body.

25. The apparatus, as recited in claim 24, wherein the oxide layer is a plasma electrolytic oxidation layer.

26. The apparatus, as recited in claim 22, wherein the plate is made of Al-SiC.

27. The apparatus, as recited in claim 26, wherein the body is formed from a material comprising aluminum, silicon, and magnesium.

28. The apparatus, as recited in claim 22, further comprising an intermediate layer between the plate and the body.
